(19) United States
(12) Patent Application Publication
(10) Pub. No.: US 2020/0279061 A1
(43) Pub. Date: Sep. 3, 2020

(54) SYSTEM AND METHODS FOR MAPPING INFRASTRUCTURE INFORMATION

(71) Applicant: BetterGIS, Inc., Novato, CA (US)

(72) Inventors: Scott A. Salas, Santa Rosa, CA (US); Moufid A. Charafeddine, New York, NY (US); Charles G. Rudkin, Novato, CA (US); Ryan L. Wallace, Novato, CA (US)

(21) Appl. No.: 16/804,284

(22) Filed: Feb. 28, 2020

Related U.S. Application Data
(60) Provisional application No. 62/812,061, filed on Feb. 28, 2019.

(51) Int. Cl. G06F 30/13; G06F 30/20; G06T 11/00

(52) U.S. Cl. CPC G06F 30/13; G06T 11/003; G06F 30/20

(57) ABSTRACT

A system and methods are provided for providing a project map to a user. The system and methods include the features of accessing a project map, where the project map includes a project image and one or more infrastructure drawings overlaid on the project image. They also include the features of inserting a plurality of items in the project map that indicate a type of utility infrastructure system on the one or more infrastructure drawings. They also include the features of inserting location information in the project map based on location information of the project image, location information of the one or more infrastructure drawings, or a combination thereof.

### CROSS REFERENCE TO RELATED APPLICATIONS

This application claims the benefit of and priority to U.S. Provisional Application No. 62/812,061, entitled, “System And Methods For Mapping Infrastructure Information,” filed on Feb. 28, 2019. The contents of which are hereby incorporated by reference in their entirety.

### TECHNICAL FIELD

The present disclosure relates virtually mapping utility infrastructure systems.

### BACKGROUND

Various individuals, such as planners, designers, builders, owners, operators, and managers (e.g., referred to generally as a user or users) may need access to information provided by a utility map. However, often the utility map is not easily accessible or is not regularly updated. This can produce risks such as project delays, increased cycle time, and increased cost. Further, utility infrastructure systems illustrated in the utility map may not be visible because of one or more obstructions, such as walls, ceilings, buildings, the ground, wells, and tunnels, as a few examples. This may create safety hazards and make it difficult to work with the utility infrastructure systems.

Therefore, a need exists for a system and related methods that provide a user interested in viewing a utility infrastructure system, such as those previously mentioned, additional information on the utility infrastructure system in a way that is readily understandable and related to the environment of the user.

Aspects of the present embodiments solve many of the above-described problems by virtually mapping a project map based on overlaid infrastructure drawings on a project image.

### SUMMARY

The present disclosure provides a system and methods for accessing a project map including one or more infrastructure drawings, a project image, and location information, along with all of the functions and methods disclosed herein.

According to one embodiment, disclosed is a memory and a control system. The memory includes a machine-readable medium storing machine-executable instructions. The control system includes one or more processors configured to execute the machine-executable instructions to access a project map that includes a project image and one or more infrastructure drawings overlaid on the project image. The one or more processors are further configured to execute the machine-executable instructions to insert a plurality of items in the project map that indicate a type of utility infrastructure system on the one or more infrastructure drawings. The one or more processors are further configured to execute the machine-executable instructions to insert location information in the project map based on location information of the project image, location information of the one or more infrastructure drawings, or a combination thereof.

In some embodiments, the one or more processors also execute the machine-executable instructions to cause a scanning of one or more utility infrastructure systems to generate the one or more infrastructure drawings. The one or more processors are further configured to execute the machine-executable instructions to receive the one or more infrastructure drawings. The one or more processors are further configured to execute the machine-executable instructions to insert the location information of the one or more infrastructure drawings. The one or more processors are further configured to execute the machine-executable instructions to overlay the one or more infrastructure drawings with the project image based on the location information of the project image and the location information of the infrastructure drawings to create the project map.

In some embodiments, the one or more processors also execute the machine-executable instructions to cause a capturing of an image of a project site to generate the project image and receive the project image. The one or more processors are further configured to execute the machine-executable instructions to insert the location information of the project image. The one or more processors are further configured to execute the machine-executable instructions to overlay the project image with the one or more infrastructure drawings based on the location information of the project image and the location information of the infrastructure drawings to create the project map.

In some embodiments, the one or more processors are configured to execute the machine-executable instructions to define one or more attributes of each of item of the plurality of items created in the project map.

In some embodiments, the one or more processors are configured to execute the machine-executable instructions to replace a stock image of a project site in the memory with the project image based on the location information of the project image.

In some embodiments, the location information associated with the project map is associated with each boundary of the project image and the one or more infrastructure drawings and correlated with a real world location.

In some embodiments, the one or more processors are configured to execute the machine-executable instructions to cause a display of a user device to present the project map based on a real world location of the user device and a perspective of the user device relative to a project site represented by the project map.

In some embodiments, the system is accessible via a user device, and the user device includes a camera configured to capture an image of a project site to generate the project image, scan one or more utility infrastructure systems to generate the one or more the infrastructure drawings, or a combination thereof.

In some embodiments, the type of utility infrastructure system includes plumbing information, electrical information, energy information, structural information, mechanical information, or other information not readily visible due to one or more obstructions.

According to another embodiment, a computer-readable storage medium carries a sequence of instructions that, when executed by a processor, cause an apparatus to: access a project map, wherein the project map includes a project image and one or more infrastructure drawings overlaid on the project image; insert a plurality of items that indicate a type of utility infrastructure system on the one or more infrastructure drawings; and insert location information in the project map based on location information of the project image, location information of the one or more infrastructure drawings, or a combination thereof.

According to another embodiment, an apparatus comprises means for: accessing a project map, wherein the project map includes a project image and one or more infrastructure drawings overlaid on the project image; inserting a plurality of items in the project map that indicate a type of utility infrastructure system on the one or more infrastructure drawings; and inserting location information in the project map based on location information of the project image, location information of the one or more infrastructure drawings, or a combination thereof.

These and other capabilities of the aspects of the present embodiments will be more fully understood after a review of the following figures, detailed description, and claims.

### BRIEF DESCRIPTION OF THE DRAWINGS

While aspects of the present embodiments are susceptible to various modifications and alternative forms, specific embodiments have been shown by way of example in the drawings and will be described in detail herein. It should be understood, however, that the embodiments are not intended to be limited to the particular forms disclosed. Rather, the disclosure is to cover all modifications, equivalents, and alternatives falling within the spirit and scope of the embodiments as defined by the appended claims.

FIG. 1 is a diagram of a virtual mapping system capable of providing a project map, according to one embodiment.

FIG. 2 is a diagram of the components of a virtual mapping platform, according to one embodiment.

FIG. 3 is a flowchart of a process for providing a project map, according to one embodiment.

FIG. 4 is a flowchart of a process for creating a project map based on scanning an infrastructure system, according to one embodiment.

FIG. 5 is a flowchart of a process for creating a project map based on capturing an image of a project site, according to one embodiment.

FIG. 6 is a diagram of a chip set that can be used to implement the embodiments of the present disclosure.

FIG. 7 is a diagram of a user interface depiction of a project map, according to one embodiment.

FIG. 8 is a diagram of an infrastructure system used to create a project map, according to one embodiment.

FIG. 9 is a diagram of an infrastructure drawing with the layers staggered, according to one embodiment.

### DETAILED DESCRIPTION

While aspects of this disclosure are susceptible of embodiment in many different forms, there is shown in the drawings and will herein be described in detail preferred embodiments with the understanding that the present disclosure is to be considered as an exemplification of the disclosed principles and is not intended to limit the broad aspect of the embodiments illustrated.

As discussed above, utility infrastructure systems often contain components that are not readily visible due to obstructions, such as walls, ceilings, the ground, buildings, wells, and tunnels, which creates risks during installation and/or maintenance of components of the utility infrastructure systems. Additionally, many users need access to utility infrastructure system information, such as planners, designers, builders, owners, operators, and managers, which can cause project delays, increase costs, and increase cycle time.

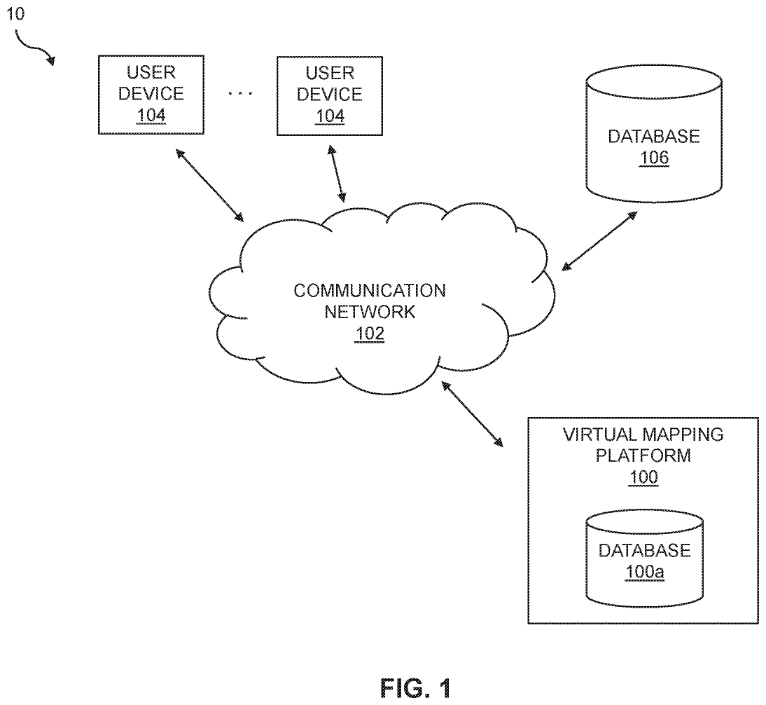

To address these problems, a virtual mapping system 10 of FIG. 1 introduces the capability to provide a project map that illustrates one or more infrastructure drawings overlaying a project image, which allows a user to easily see elements of the infrastructure drawings relative to elements in the project image. Thus, a user can visually understand where elements of the infrastructure are in relation to an object within the surrounding environment of the user; the object being an element in the project image. The project map also can be manipulated based on the user manipulating a user device that presents the project map on a corresponding display. This allows a user to better grasp aspects of the project site through a better understanding of what is shown in the one or more infrastructure drawings overlaying a project image representative of the project map.

The virtual mapping system 10 includes a virtual mapping platform 100 that is connected to a communication network 102. Also connected to the communication network 102 are one or more user devices 104 and one or more databases 106. In one or more embodiments, the virtual mapping platform 100 also can include one or more databases 100a. In one or more embodiments, the one or more databases 106 can be omitted if the virtual mapping platform 100 includes the one or more databases 100a, or the one or more databases 100a can be omitted if the virtual mapping system 10 includes the one or more databases 106.

The virtual mapping platform 100 provides the underlying functionality of the virtual mapping system 10 related to providing a project map to a user, such as via a user device 104, and manipulating the project map based on, for example, an orientation of the user, among other functionality. Thus, in one or more embodiments, the virtual mapping platform 100 can be implemented via any suitable distributed computer system, a server, or on one or more of the user devices 104.

The user devices 104 provide access to the virtual mapping platform 100 for users of the user devices 104. In one or more embodiments, the user devices 104 can be any type of computing device, such as desktop, a laptop, a tablet, a smart phone, virtual reality goggles or glasses, and the like that can communicate with the virtual mapping platform 100. Thus, the user devices 104 can be any suitable user device configured to display one or more project images, one or more project maps, one or more infrastructure drawings, and the other features disclosed herein.

In one or more embodiments, the virtual mapping platform 100, the databases 100a, or both can reside on one or more of the user devices 104. In other words, software, firmware, or hardware of the user device 104 can execute the functionality described herein as being performed by the virtual mapping platform 100, and can store information described herein as being stored in the databases 100a. In which case, the communication network 102 can be omitted from the virtual mapping system 10. Alternatively, in which case, the communication network 102 can still be part of the virtual mapping system 10, but used instead for the user devices 104 communicating with the databases 106.

In coordination with the virtual mapping platform 100, the user devices 104 can be configured to access a project image, one or more infrastructure drawings, and/or a project map. The user devices 104 can access the virtual mapping platform 100 through the communication network 102 for accessing or loading a project image, one or more infrastructure drawings, and/or a project map and present the same to a user of the user device 104.

The user devices 104 can include one or more components for interfacing with the virtual mapping platform 100, including a central processing unit (CPU), a user interface, a communication interface, an operating system, a network communication module, and a client application configured to access the virtual mapping platform 100. In one or more embodiments, the client application can simply be a web browser that can navigate to a web page associated with the virtual mapping platform 100. The user interface of the user devices 104 can include components including but not limited to a display, a keyboard, a touchscreen, or a combination thereof. It is contemplated that the functions of these components can be combined in one or more components or performed by other components of equivalent functionality.

In one or more embodiments, the user devices 104 can be configured with one or more sensors including, but not limited to, any one or more of any of, for example a GPS sensor, a location sensor, an orientation sensor, an accelerometer, and the like. In this regard, the user devices 104 can detect the location of the user devices 104, and a user associated with the user devices 104, in addition to the orientation of the user devices 104 and/or user at a project site. This information can be transmitted to the virtual mapping platform 100 for processing so that the virtual mapping platform 100 can provide information to the user devices 104 that allows the user devices 104 to orient the project image, the one or more infrastructure drawings, the project map, or combinations thereof according to the orientation of the user relative to, for example, a project site. Thus, user devices 104 can be configured to arrange the project image, the one or more infrastructure drawings, the project map, or combinations thereof in the display of user devices 104 based on the location and perspective or orientation of user devices 104. Moreover, the virtual mapping platform 100, the user devices 104, or both are configured to continuously monitor the location and/or orientation of the user devices 104 and change the orientation of the project image, the one or more infrastructure drawings, or project map in the display of the user devices 104 based on the change in location and orientation of user devices 104. In this way, the project image, the one or more infrastructure drawings, the project map, or combinations thereof may adjust in real time to the movement of the user devices 104 or the user throughout the project site.

In one or more embodiments, the user devices 104 can be configured to display the project site map relative to the actual environment of the project site. In this regard, the user devices 104 can be configured to present infrastructure items to a user via the display of the user devices 104 in the environment in which the user exists, such as at the project site. For example, user devices 104 can be configured to present the project map relative to the project site and relative to the perspective of the user based on the location and orientation of user devices 104, such as based on the orientation of smart glasses. In this way, the user can look at a particular portion of the project site and select portions of the project map to be viewable such that the user sees the project map disposed over the physical structures of the project site. For example, the user devices 104 can be smart goggles or glasses that overlay information of the project map on the real-world view of a project site. This provides a user with an augmented reality view of the project site, and provides the user with a better understanding of infrastructure that may be otherwise not viewable based on being behind one or more obstructions.

One or both of the databases 100a and databases 106 store information used in the performance of the functionality of the virtual mapping system 10, such as storing one or more project maps, one or more project images, one or more infrastructure drawings, one or more utility infrastructure systems, and information on items or elements within any of the project maps, project images, infrastructure drawings, utility infrastructure systems, etc. For example, the database 100a stores and provides to a user device 104 utility infrastructure system information.

The communication network 102 can be any type of communication network, such as the Internet, a wide area network (WAN), and local area network (LAN), etc. The communication network 102 allows two or more devices to exchange information although the devices are remote from each other.

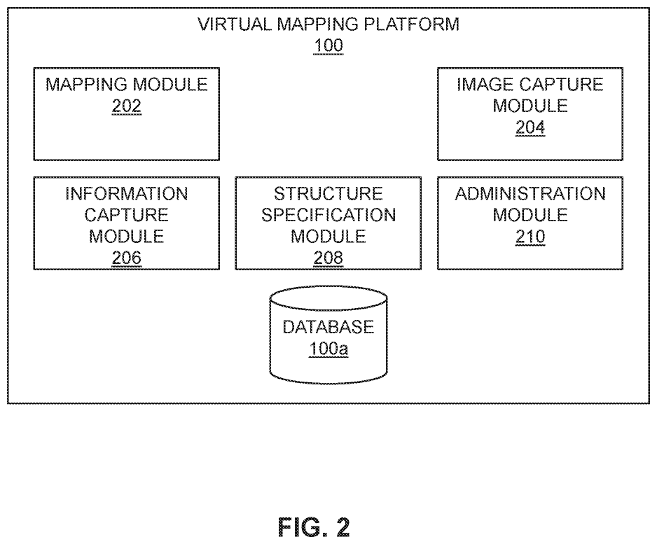

FIG. 2 is a diagram of the components of the virtual mapping platform 100, according to one embodiment. The virtual mapping platform 100 includes a mapping module 202, an image capture module 204, an information capture module 206, a structure specification module 208, an administration module 210, along with the database 100a. The various modules represent one or more software, firmware, and/or hardware functions and/or routines that are executed or performed by the virtual mapping platform 100. For example, for the virtual mapping platform 100 being executed in a cloud architecture, the various modules can be one or more functions performed by hardware that is executing the functionality of the virtual mapping platform 100.

The mapping module 202 is configured to overlay one or more infrastructure drawings on to the project image. The one or more infrastructure drawings are digital representations of one or more utility infrastructure systems. The one or more utility infrastructure systems are, for example, blueprints or other types of drawings, charts, etc. that provide information, such as routing and location, of various utilities at a project site. In this regard, the one or more infrastructure drawings can be a digitized image, video, or other file type that can be translucently imposed on the project image. This allows for correlation between elements on the one or more infrastructure drawings and elements present in the project image. The project image is a digital representation of a project site, such as an aerial image of a project site that provides a similar view of the project site as a schematic drawing.

The mapping module 202 can further be configured to correlate a structure on the project image with an item in one or more infrastructure drawings. This correlation allows the structure in the one or more infrastructure drawings and the item in the project image to be located relative to one another. This also allows the location information imbedded in the project image to be correlated with the one or more infrastructure drawings. The correlation of location information and item information in the one or more infrastructure drawings allows for various items to be correlated between their real world location and the one or more infrastructure drawings.

Further, in one or more embodiments, the mapping module 202 is configured to align the one or more infrastructure drawings with the project image based on and in response to the above correlating. The alignment of the one or more infrastructure drawings with the project image allows the structures from the one or more infrastructure drawings to be superimposed or placed on the project image. The alignment also facilitates the creation of the project map, which contains the structures and attributes in the one or more infrastructure drawings that are aligned locationally with the visual structure in the project image. Thus, the project map is an interactive map with the physical location of real world structures based on the attributes obtained from the one or more infrastructure drawings.

In one or more embodiments, the mapping module 202 is configured to insert a plurality of items represented on the one or more infrastructure drawings on the project image. In this regard, the mapping module 202 may take the digitized information captured or received by, for example, the image capture module 204 and/or the information capture module 206 (discussed below) and use that digitized information, along with correlating structure, and then find in the project image to create items on the project site map. These items may correspond to utility infrastructure systems including, for example, water infrastructure, electrical infrastructure, heating and cooling (HVAC) infrastructure, gas infrastructure, lighting infrastructure, irrigation infrastructure, and/or the like. Moreover, because of the alignment and locational correlation between the one or more infrastructure drawings and the project image, the mapping module 202 can be configured to locate the structures in the project image, along with the locational information of the structure in the project image.

The image capture module 204 is configured to create, or cause the creation of, a project image of a project site. The project image can be one or more high resolution photographs or videos. In one or more embodiments, the image capture module 204 can be configured to cause a capturing of one or more project images of a project site. In one or more embodiments, the image capture module 204 can be configured to interface with a user device 104 that is configured to capture an image, such as a user device 104 with a camera. The image capture module 204 can cause the user device to take a picture of a project site, using the camera, to generate the project image. In one or more alternative embodiments, where the virtual mapping platform 100 is, for example, being executed on a user device, the image capture module 204 can cause the camera integrated in the user device 104, or in communication with the user device 104, to capture a picture of the project site to generate the project image. Alternatively, or in addition, the image capture module 204 can be configured to access the databases 100a and/or 106 to retrieve one or more project images associated with a project site. The one or more project images can be retrieved based on, for example, location information associated with the project site corresponding to location information of the one or more project images in the databases 100a/106.

Image capture module 204 can also be configured to associate location information with the project image. In this regard, the project image may be correlated with a real world location of the actual project site. Location information may be associated with each corner or edge of the project image so that the actual coordinates in the real world are known and associated with the project image.

The information capture module 206 is configured to cause a scanning of one or more paper drawings (e.g., schematics) of one or more utility infrastructure systems to generate the one or more infrastructure drawings. In one or more embodiments, the information capture module 206 can be configured to interface with a user device 104 that is configured to scan an image, such as a user device 104 with a camera or a scanner, or in communication with a camera or scanner. The information capture module 206 can cause the user device 104 to scan the utility infrastructure systems, using the camera or scanner, to generate the one or more infrastructure drawings. In one or more alternative embodiments, where the virtual mapping platform 100 is being executed on a user device 104, the information capture module 206 can cause the camera and/or scanner integrated in the user device 104, or in communication with the user device 104, to scan the utility infrastructure systems to generate the one or more infrastructure drawings.

The information capture module 206 can then analyze the one or more infrastructure drawings and digitize the structures in those documents. Moreover, the information capture module 206 can contribute to a value with the various structures and symbols in the one or more infrastructure drawings to determine attributes about the various utilities structures.

The structure specification module 208 is configured to define one or more attributes of each of the items in the plurality of items created in the project site map. In this regard the structure specification module 208 is configured to collect attribute information from a plurality of databases or information sources, such as the databases 106. These attributes and information may be collected from publicly available sources, the one or more utility infrastructure systems, look up tables, and/or the like.

In one or more embodiments, the structure specification module 208 is configured to select a first item from the plurality of items placed in the project image. The structure specification module 208 is then configured to analyze the first item. In this regard, the structure specification module 208 can define the utility structure associated with the item based on the attributes in the project image and or the attributes associated with the item in the one or more utility infrastructure systems and/or the one or more infrastructure drawings. Moreover, the structure specification module 208 can be configured to retrieve attributes for the utility structure. In this regard, the structure specification module 208 can build an attribute database or attribute table associated with each utility structure in the project site map. This attribute table or database may be selectable by a user and provided to a user device 104 for use by a user with technical attributes for each utility structure allowing for quick reference about the utility structure in the field by the user.

In one or more embodiments, the mapping module 202 and/or the structure specification module 208 can be configured to associate the attributes defined by the structure specification module 208 with the item at the location of the item in the project map, which is associated with location information in the project image. In this regard, the attribute information is accessible in the field by a user at the location of the structures at the project site.

In one or more embodiments, the administration module 210 can be configured to associate and/or locate a project image in an image database, such as in one or both of the database 100a or 106. In this regard, the administration module 210 can be configured to evaluate the location information associated with the project image. In response to determining the actual location of the project image and its boundaries, the corresponding location of the project image in the image database can be identified. One or more related images in the database, or the original project image, can then be replaced by the project image based associated with the identified boundaries, such as the location of each edge of the image project image, and the like. The administration module 210 can then be configured to replace the original project image of the project site, which might not have information that the virtual mapping platform 100 associates with the project image, in the image database with the project image based on the location information associated with the project image.

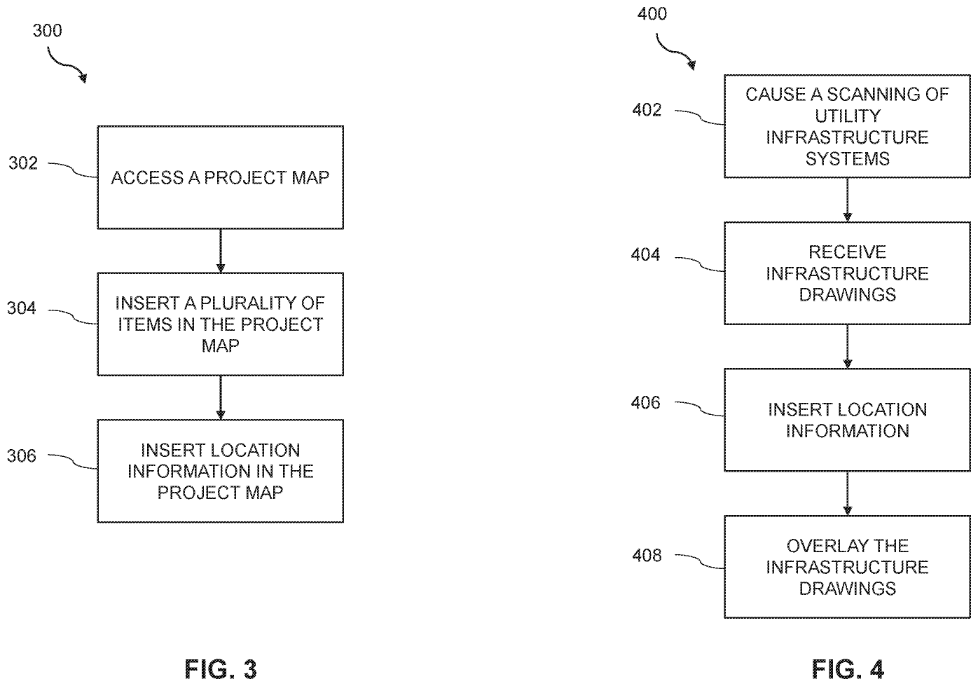

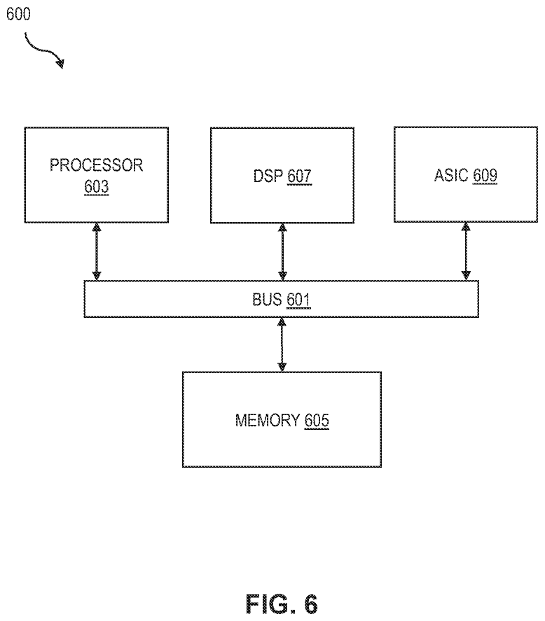

FIG. 3 is a flowchart of a process 300 for providing a project map, according to one embodiment. The virtual mapping platform 100 performs the process 300 and is implemented in, for example, a chip set including a processor and a memory as illustrated in FIG. 6.

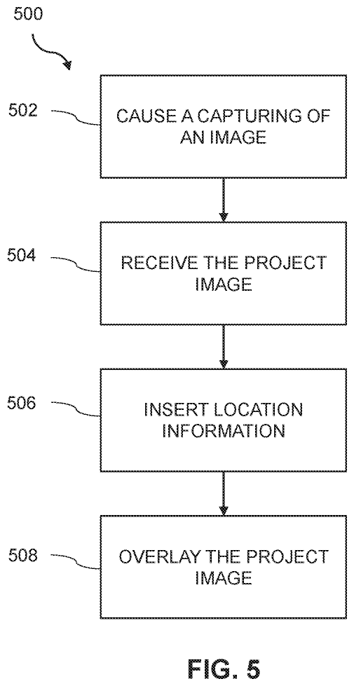

At step 302, the virtual mapping platform 100 accesses a project map. As discussed above, the project map includes a project image and one or more infrastructure drawings overlaid on the project image. The virtual mapping platform 100 can access the project map by, for example, accessing the project map in one of the databases 100a and/or 106. Thus, the project map may have already been created by the virtual mapping platform 100, and step 302 can include merely accessing the project map. As described below with respect to FIGS. 4 and 5, the accessing can also occur after the virtual mapping platform 100 creates the project map.

At step 304, the virtual mapping platform 100 inserts items in the project map that indicate the type of infrastructure system on the infrastructure drawings. As discussed above, these items may correspond to utility infrastructure systems including, for example, water infrastructure, electrical infrastructure, heating and cooling (HVAC) infrastructure, gas infrastructure, lighting infrastructure, irrigation infrastructure, and the like. In one or more embodiments, the attributes of each of the items in the plurality of items can be inserted in the project map. This attribute information can be collected from a plurality of databases or information sources. The attributes can, for example, define the utility structure associated with the item. An attribute table associated with each utility structure in the project map can be generated for the project map, which allows a user to select an item on the project map to receive information on the item. For example, attribute information is selectable by a user and provides the user with technical attributes for each utility structure shown in the project image, allowing for quick reference about the utility structure in the field around the user at the project site.

At step 306, the virtual mapping platform 100 inserts location information in the project map based on location information of the project image, location information of the one or more infrastructure drawings, or a combination thereof. The location information ties the items in the project map to their real-world location at the project site. In one or more embodiments, the attributes of the items discussed above can be associated with the location of the item in the project map. In this regard, the attribute information is accessible in the field at the location of the items shown in the project map.

The process 300 of FIG. 3 allows a user at a project site to access a project map, that includes one or more infrastructure drawings overlaid on a project map to obtain information on items within the project map. The user can also correlate the location of the item in the project map with the real-world location of the item in the project site. This affords the user with a better understanding of the item relative to the project site.

FIG. 4 is a flowchart of a process 400 for creating a project map from a scanning of a utility infrastructure system, according to one embodiment. The virtual mapping platform 100 performs the process 400 and is implemented in, for example, a chip set including a processor and a memory as illustrated in FIG. 6.

At step 402, the virtual mapping platform 100 causes a scanning of a utility infrastructure system to generate one or more infrastructure drawings. As described above, the virtual mapping platform 100 can be configured to cause a scanning of paper drawings of utility infrastructure systems, such as by directing a user device 104 that includes or is in communication with a scanner, to scan the utility infrastructure systems. Alternatively, where the virtual mapping platform 100 is at a user device 104, the virtual mapping platform 100 can directly instruct the scanner integrated in or in communication with the user device 104 to scan the one or more utility infrastructure systems. The virtual mapping platform 100 can then analyze the scanned documents and digitize the structures in those documents. Moreover, the virtual mapping platform 100 can contribute to a value with the various structures and symbols in the scan to determine attributes of the various utilities structures.

At step 404, the virtual mapping platform 100 receives the one or more infrastructure drawings. Where the virtual mapping platform 100 does not reside on the device, such as the user device 104, that is performing the scanning or in communication with the scanner, at step 404, the one or more infrastructure drawings are transmitted to the virtual mapping platform 100. Where the virtual mapping platform 100 does reside on the device that is performing the scanning or in communication with the scanner, the virtual mapping platform 100 receives the one or more infrastructure drawings, such as by accessing the location of the memory that is storing the scanned one or more infrastructure drawings.

At step 406, the virtual mapping platform 100 inserts location information of the one or more infrastructure drawings. In one or more embodiments, the virtual mapping platform 100 can read indicia on the one or more infrastructure drawings that indicate location information contained in the one or more infrastructure drawings. The virtual mapping platform 100 can digitize this information and associate the information with the one or more infrastructure drawings, either as a whole or with respect to one or more items within the one or more infrastructure drawings. The virtual mapping platform 100 can also associate location information with respect to, for example, the borders of the one or more infrastructure drawings with the corresponding real-world location of the one or more infrastructure drawings relative to the project site. The location information allows the one or more infrastructure drawings to be correlated and overlaid on the project image, as described above and specifically described below with respect to the next step.

At step 408, the virtual mapping platform 100 overlays the one or more infrastructure drawings with the project image based on the location information of the project image and the location information of the infrastructure drawings to create the project map. The overlaying of the one or more infrastructure drawings with the project image allows for a correlation between elements on the infrastructure drawings and elements present in the project image. The overlaying also allows for a correlation of a structure on the project image with an item in the infrastructure drawing. This correlation allows the structure in the drawing and the item in the project image to be located relative to one another. This also allows the location information imbedded in the image to be correlated with the infrastructure drawing. The correlation of location information and item information in the infrastructure drawing allows for various items to be correlated between their real-world location and the infrastructure drawing.

The process 400 of FIG. 4 allows a user to digitize one or more infrastructure drawings to create a project map by combining the one or more infrastructure drawings with a project image of a project site. The result is the project map that can be used in the field to allow a user to more accurately visualize where at a project site items are in one or more infrastructure drawings. The process 400 can be executed by the virtual mapping platform 100 if, for example, one or more infrastructure drawings and/or a project map of a project site have not already been created.

FIG. 5 is a flowchart of a process 500 for creating a project map from a capturing of an image, according to one embodiment. The virtual mapping platform 100 performs the process 500 and is implemented in, for example, a chip set including a processor and a memory as illustrated in FIG. 6.

At step 502, the virtual mapping platform 100 causes a capturing of an image of a project site to generate the project image. As described above, the virtual mapping platform 100 can be configured to cause a capturing of an image of a project site, such as by directing a user device 104 that includes or is in communication with a camera, to take a picture of the project site. Alternatively, where the virtual mapping platform 100 is at a user device 104, the virtual mapping platform 100 can directly instruct the camera integrated in or in communication with the user device 104 to capture the project image. The virtual mapping platform 100 can then analyze the captured project image and digitize the structures in the image.

At step 504, the virtual mapping platform 100 receives the project image. Where the virtual mapping platform 100 does not reside on the device, such as the user device 104, that is performing the capturing or in communication with the camera, at step 504, the one or more infrastructure drawings are transmitted to the virtual mapping platform 100. Where the virtual mapping platform 100 does reside on the device that is performing the capturing or in communication with the camera, the virtual mapping platform 100 receives the project image, such as by accessing the location of the memory that is storing the captured project image.

At step 506, the virtual mapping platform 100 inserts the location information of the project image. In one or more embodiments, the virtual mapping platform 100 can receive with the project image GPS information associated with where the project image was taken. The virtual mapping platform 100 can insert this GPS information in the project image. The virtual mapping platform 100 can also digitize information in the project image, such as by defining boundaries and or obstructions in the project image. For example, the virtual mapping platform 100 can associate location information with respect to outlines in the project image that relate to real-world locations of one or more structures in the project image. The location information allows the project image to be correlated and have one or more infrastructure drawings overlaid on the project image, as described above and specifically described below with respect to the next step.

At step 508, the virtual mapping platform 100 overlays the project image with the one or more infrastructure drawings based on the location information of the project image and the location information of the infrastructure drawings to create the project map. The overlaying of the one or more infrastructure drawings with the project image allows for a correlation between elements on the infrastructure drawings and elements present in the project image. The overlaying also allows for a correlation of a structure on the project image with an item in the infrastructure drawing. This also allows the location information imbedded in the image to be correlated with the infrastructure drawing. The correlation of location information and item information in the infrastructure drawing allows for various items to be correlated between their real-world location and the infrastructure drawing.

In one or more embodiments, the virtual mapping platform 100 can perform one or more alterations on one or more of the infrastructure drawings and the project image so that the infrastructure drawings can be aligned with and overlaid on the project image. For example, the virtual mapping platform 100 can perform one or more re-sizing alterations, one or more perspective alterations, one or more color and/or transparency alterative, etc. so that the infrastructure drawings can be aligned with the project map.

Although the processes 400 and 500 are described as being performed as two separate processes, in one or more embodiments, the processes 400 and 500 can be combined. For example, in the situation where there are no infrastructure drawing and no project image of a project site, the virtual mapping platform 100 can perform both processes 400 and 500 in the creation of the project map. The order of the steps of the 400 and 500 can vary from the order of the description of the steps herein.

The processes described herein for accessing a project map may be advantageously implemented via software, hardware, firmware, or a combination thereof. Such exemplary hardware for performing the described functions is detailed below.

FIG. 6 illustrates a chip set or chip 600 upon which the embodiments of the present disclosure can be implemented. In one embodiment, the chip set or chip 600 includes a communication mechanism such as a bus 601 for passing information among the components of the chip set 600. A processor 603 has connectivity to the bus 601 to execute instructions and process information stored in, for example, a memory 605. The processor 603 may include one or more processing cores with each core configured to perform independently. A multi-core processor enables multiprocessing within a single physical package. Examples of a multi-core processor include two, four, eight, or greater numbers of processing cores. The processor 603 may also be accompanied with one or more specialized components to perform certain processing functions and tasks, such as one or more digital signal processors (DSP) 607, or one or more application-specific integrated circuits (ASIC) 609. A DSP 607 typically is configured to process real-world signals (e.g., sound) in real time independently of the processor 603. Similarly, an ASIC 609 can be configured to perform specialized functions not easily performed by a more general purpose processor.

In one embodiment, the chip set or chip 600 includes merely one or more processors and some software and/or firmware supporting and/or relating to and/or for the one or more processors. The processor 603 and accompanying components have connectivity to the memory 605 via the bus 601. The memory 605 includes both dynamic memory (e.g., RAM, magnetic disk, writable optical disk, etc.) and static memory (e.g., ROM, CD-ROM, etc.) for storing executable instructions that when executed perform the steps described herein for any of the functionality, methods, and/or processes. The memory 605 also stores the data associated with or generated by the execution of the steps.

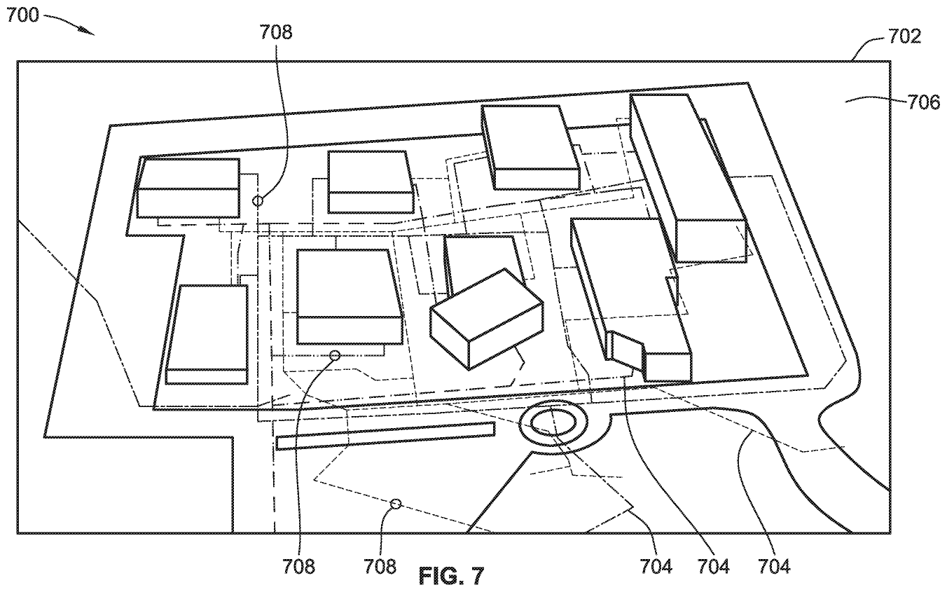

FIG. 7 is a diagram of a user interface depiction 700 of a project map 702, according to one embodiment. When viewing the user interface depiction 700 on a user device 104, the user can see the infrastructure drawings 704 overlaid on a project image 706, thereby forming the project map 702. The infrastructure drawings 704 include indicators 708 that indicate the type of utility infrastructure systems represented by the infrastructure drawings 704 in the project map 702. As described above, as the orientation of the user device 104 changes, so to can the orientation of the project map 702 within the user interface depiction 700. Thus, the project map 702 can be modified based on a user's real world location and perspective at a project site while viewing the project map 702 on the user device 104.

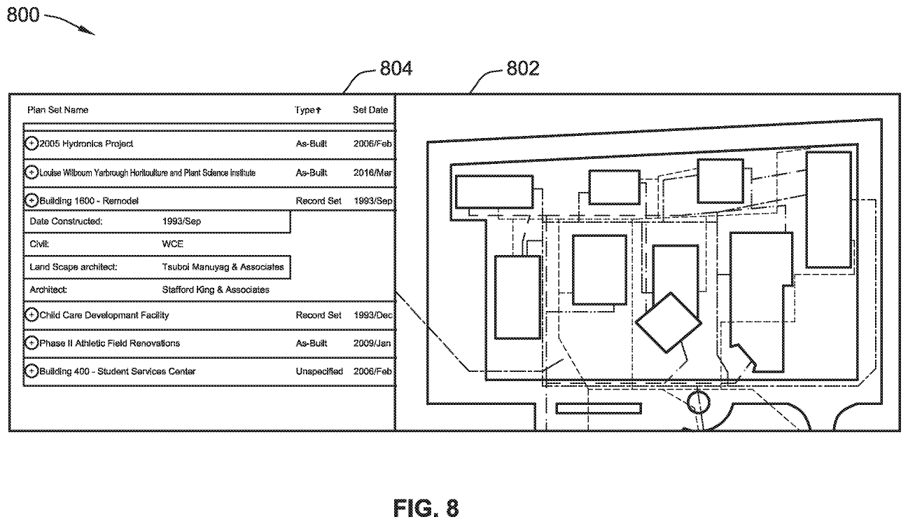

FIG. 8 is a diagram of a user interface depiction 800 of a user interacting with the virtual mapping platform 100, according to one embodiment. The user interface depiction 800 includes a project map 802 next to an information panel 804. The information on the information panel 804 can include project a name, a project stage, a location, a manager, a builder, a designer, an architect, various relevant dates, or any combination thereof. This information can further display information associated with any one or more of infrastructure drawings within the project map 802, items within the project map 802, and the like.

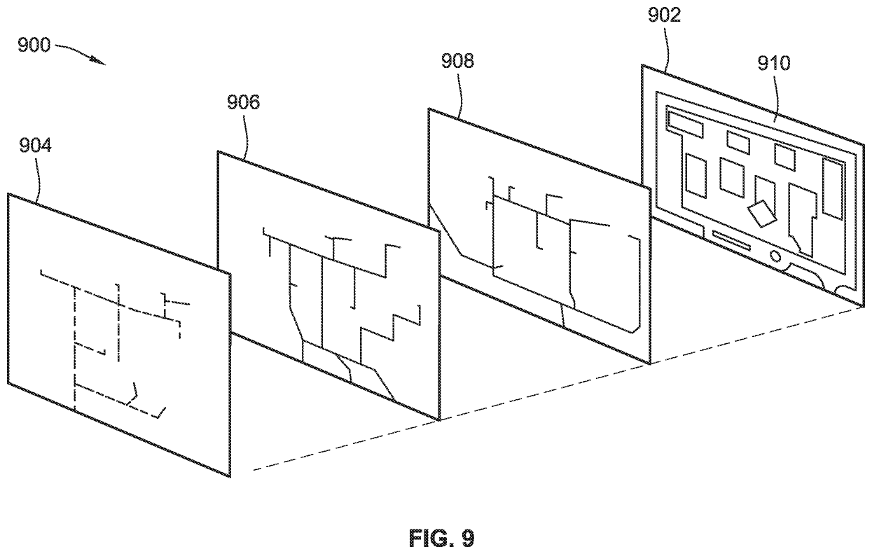

FIG. 9 is a diagram of a user interface depiction 900 of a project map 902, according to one embodiment. The project map 902 is shown in an exploded view to illustrate how the infrastructure drawings 904, 906, and 908 are overlaid on a project image 910 to form the project map 902. The layers of the infrastructure drawings 904, 906, and 908 can be communications, lighting, gas, HVAC, water, electric, and sewer infrastructure drawings and are overlaid on the project image 910 according to the alignment of the elements within the infrastructure drawings 904, 906, and 908 aligning with the elements shown in the project image 910.

For purposes of the present detailed description, the singular includes the plural and vice versa (unless specifically disclaimed); the words “and” and “or” shall be both conjunctive and disjunctive; the word “all” means “any and all”; the word “any” means “any and all”; and the word “including” means “including without limitation.” Additionally, the singular terms “a,” “an,” and “the” include plural referents unless context clearly indicates otherwise.

While aspects of the present disclosure have been described with reference to one or more particular embodiments, those skilled in the art will recognize that many changes may be made thereto without departing from the spirit and scope of the present disclosure. Each of these embodiments and obvious variations thereof is contemplated as falling within the spirit and scope of the present disclosure. It is also contemplated that additional embodiments according to aspects of the present disclosure may combine any number of features from any of the embodiments described herein.

What is claimed is:

1. A system comprising:
a memory comprising a machine-readable medium storing machine-executable instructions; and
a control system comprising one or more processors, the one or more processors being configured to execute the machine-executable instructions to:
access a project map, wherein the project map includes a project image and one or more infrastructure drawings overlaid on the project image;
insert a plurality of items in the project map that indicate a type of utility infrastructure system on the one or more infrastructure drawings; and
insert location information in the project map based on location information of the project image, location information of the one or more infrastructure drawings, or a combination thereof.

2. The system of claim 1, wherein the one or more processors are configured to execute the machine-executable instructions to:
cause a scanning of one or more utility infrastructure systems to generate the one or more infrastructure drawings;
receive the one or more infrastructure drawings;
insert the location information of the one or more infrastructure drawings; and
overlay the one or more infrastructure drawings with the project image based on the location information of the project image and the location information of the infrastructure drawings to create the project map.

3. The system of claim 1, wherein the one or more processors are configured to execute the machine-executable instructions to:
cause a capturing of an image of a project site to generate the project image;
receive the project image;
insert the location information of the project image; and
overlay the project image with the one or more infrastructure drawings based on the location information of the project image and the location information of the infrastructure drawings to create the project map.

4. The system of claim 1, wherein the one or more processors are configured to execute the machine-executable instructions to define one or more attributes of each of item of the plurality of items created in the project map.

5. The system of claim 1, wherein the one or more processors are configured to execute the machine-executable instructions to replace a stock image of a project site in the memory with the project image based on the location information of the project image.

6. The system of claim 1, wherein the location information associated with the project map is associated with each boundary of the project image and the one or more infrastructure drawings and correlated with a real world location.

7. The system of claim 1, wherein the one or more processors are configured to execute the machine-executable instructions to cause a display of a user device to present the project map based on a real world location of the user device and a perspective of the user device relative to a project site represented by the project map.

8. The system of claim 1, wherein the system is accessible via a user device, and the user device includes a camera configured to capture an image of a project site to generate the project image, scan one or more utility infrastructure systems to generate the one or more the infrastructure drawings, or a combination thereof.

9. The system of claim 1, wherein the type of utility infrastructure system includes plumbing information, electrical information, energy information, structural information, mechanical information, or other information not readily visible due to one or more obstructions.

10. A method comprising:
accessing a project map, wherein the project map includes a project image and one or more infrastructure drawings overlaid on the project image;
inserting a plurality of items in the project map that indicate a type of utility infrastructure system on the one or more infrastructure drawings; and
inserting location information in the project map based on location information of the project image, location information of the one or more infrastructure drawings, or a combination thereof.

11. The method of claim 10, further comprising:
causing a scanning of one or more utility infrastructure systems to generate the one or more infrastructure drawings;
receiving the one or more infrastructure drawings;
inserting the location information of the one or more infrastructure drawings; and
overlaying the one or more infrastructure drawings with the project image based on the location information of the project image and the location information of the infrastructure drawings to create the project map.

12. The method of claim 10, further comprising:
causing a capturing of an image of a project site to generate the project image;
receiving the project image;
inserting the location information of the project image; and
overlaying the project image with the one or more infrastructure drawings based on the location information of the project image and the location information of the infrastructure drawings to create the project map.

13. The method of claim 10, further comprising defining one or more attributes of each item of the plurality of items created in the project map.

14. The method of claim 10, further comprising replacing a stock image of a project site in a database with the project image based on the location information of the project image.

15. The method of claim 10, wherein the location information associated with the project map is associated with each boundary of the project image and the one or more infrastructure drawings and correlated with a real world location.

16. The method of claim 10, further comprising causing a display on a user device of the project map based on a real world location of the user device and a perspective of the user device relative to a project site represented by the project map.

17. The method of claim 10, further comprising:
capturing an image of a project site with a camera to generate the project image; and
scanning one or more utility infrastructure systems to generate the one or more the infrastructure drawings.

18. The method of claim 10, wherein the type of utility infrastructure system includes plumbing information, electrical information, energy information, structural information, mechanical information, or other information not readily visible due to one or more obstructions.

19. A memory or structure of a memory comprising:
a memory comprising a machine-readable medium storing machine-executable instructions; and
a control system comprising one or more processors, the one or more processors being configured to execute the machine-executable instructions to:
access a project map, wherein the project map includes a project image and one or more infrastructure drawings overlaid on the project image;
insert a plurality of items in the project map that indicate a type of utility infrastructure system on the one or more infrastructure drawings; and
insert location information in the project map based on location information of the project image, location information of the one or more infrastructure drawings, or a combination thereof.
